(19) United States
(12) Patent Application Publication
(10) Pub. No.: US 2010/0134675 A1
(43) Pub. Date: Jun. 3, 2010

(54) SOLID-STATE IMAGING DEVICE AND MANUFACTURING METHOD THEREOF

(75) Inventors: Kei TOYOTA, Osaka (JP); Yoshihiro TOMITA, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/626,007

(22) Filed: Nov. 25, 2009

(30) Foreign Application Priority Data
Dec. 2, 2008 (JP) 2008-307998

(51) Int. Cl. H04N 5/335; H01L 31/0232

(52) U.S. Cl. 348/311; 438/65; 257/E31.127

(57) ABSTRACT

A solid-state imaging device according to the present invention includes a semiconductor substrate, a solid-state imaging element formed on the semiconductor substrate, and a transparent member placed on the solid-state imaging element. The solid-state imaging element includes light receiving units each of which is formed on the semiconductor substrate, and digital microlenses each of which is formed above an associated one of the light receiving units. Each of the digital microlenses has protruding portions and recessed portions, and each of the protruding portions and the recessed portions are alternately arranged in a concentric pattern. The protruding portions are placed in contact with the transparent member, and the recessed portions make no contact with the transparent member.

### BACKGROUND OF THE INVENTION

(1) Field of the Invention

The present invention relates to a solid-state imaging device and a manufacturing method thereof, in particular, to a solid-state imaging device including a digital microlens.

(2) Description of the Related Art

A typical solid-state imaging element equipped with a Charge Coupled Device (CCD) has, as a condensing lens on a light receiving unit, a microlens with an organic material cured in the form of a lens. Such a solid-state imaging element is ceramic-packaged and included in conventional solid-state imaging devices.

Described hereinafter is a conventional solid-state imaging device including a ceramic-packaged solid-state imaging element; namely a solid-state imaging device 500.

FIG. 14 illustrates a cross-sectional view of the solid-state imaging device 500. As shown in FIG. 14, the solid-state imaging device 500 includes a laminated ceramic package 111, a solid-state imaging element 113, a wire 117, a light shielding layer 121, a guard glass board 123, and sealing compound 127.

Formed out of laminated ceramic plates, the laminated ceramic package 111 includes a recessed portion 111a and an inside lead portion 111b.

The solid-state imaging element 113; namely an LSI (Large Scale Integrated circuit), is disposed in the recessed portion 111a which the laminated ceramic package 111 has.

The solid-state imaging element 113 includes a light-receiving area 113a in which light receiving units are arranged in a plane, a surrounding circuit unit 113A disposed outside the light-receiving area 113a, an input-output unit 113b formed in a part of the surrounding circuit unit 113A, and an electrode pad 113c formed on the surface of the input-output unit 113b.

Moreover, the solid-state imaging element 113 includes a microlens (not shown) with an organic material cured in the form of a lens. Formed on the light-receiving area 113a, the microlens guides incident light to the light-receiving area 113a.

The wire 117 connects the electrode pad 113c and the inside lead portion 111b.

Formed above the solid-state imaging element 113 is the guard glass board 123 via a void 124 (air).

The light shielding layer 121 covers a top-outer periphery, an edge face (side face), and a bottom-outer periphery of the guard glass board 123. The light shielding layer 121 is formed to prevent reflected light from the wire 117 from entering in the light-receiving area 113a.

Filled between the guard glass board 123 and the laminated ceramic package 111 is the sealing compound 127.

Meanwhile, a recent technique replaces a microlens formed out of the organic material with a digital microlens (See Patent Reference 1, for example).

FIG. 15 illustrates a cross-sectional view showing a structure of a solid-state imaging element including a digital microlens 57. FIG. 16 illustrates a top view of the digital microlens 57.

As shown in FIGS. 15 and 16, the digital microlens 57 is made of SiO₂ (dioxide silicon) having a fine trench formed with a use of a semiconductor micro-fabrication technique. The fine trench is as short as light wavelength or shorter. The digital microlens 57 has protruding portions 60 and recessed portions (trenches) 61 each alternately arranged in a concentric pattern.

Compared with a microlens formed out of an organic material, the digital microlens 57, formed out of an inorganic material, enjoys greater advantages in heat-resistance and weather-resistance.

Patent Reference 1: Japanese Unexamined Patent Application Publication No. 2008-10773

### SUMMARY OF THE INVENTION

Such a solid-state imaging device could be smaller and thinner.

Hence, the present invention has as an object to provide a solid-state imaging device which achieves excellent heat-resistance and weather-resistance as well as a thin profile, and a manufacturing method thereof.

In order to achieve the above object, a solid-state imaging device in accordance with a first aspect of the present invention includes: a semiconductor substrate; a solid-state imaging element formed on the semiconductor substrate; and a transparent member placed on the solid-state imaging element, wherein the solid-state imaging element has: light receiving units each of which is formed on the semiconductor substrate; and digital microlenses each of which is formed above an associated one of the light receiving units, each of the digital microlenses has protruding portions and recessed portions, each of the protruding portions and the recessed portions being alternately arranged in a concentric pattern, and the protruding portions are placed in contact with the transparent member and the recessed portions make no contact with the transparent member.

According to this structure the top surfaces of the digital microlenses are placed in contact with the under surface of the transparent member. This makes possible reducing the thickness of the solid-state imaging device compared with the case where the transparent member is placed over the digital microlenses (or microlenses formed out of an organic material) via a void. Further, the solid-state imaging device in the first aspect of the present invention uses the digital microlenses to achieve improvement in heat-resistance and weather-resistance. Thus, the present invention can provide a thin solid-state imaging device which enjoys excellent heat-resistance and weather-resistance.

The transparent member may be placed in contact and fixed with the protruding portions via the transparent adhesive, and a bottom surface and a side surface of each of the recessed portions may make no contact with the transparent adhesive.

This structure makes possible easily attaching the transparent member to the digital microlenses, using the transparent adhesive.

The bottom surface and the side surface of each of the recessed portions may be hydrophobized so as to form a hydrophobized layer.

This structure makes possible keeping wettability little between the surfaces of the recessed portions of the digital microlenses and the transparent adhesive. This can prevent the transparent adhesive from flowing into each of the recessed portions and keep the void of the recessed portion from being filled with the transparent adhesive when applying the transparent adhesive on the top surface of each of the protruding portions.

The solid-state imaging device may further include fillet which is made of adhesive and bonds with i) a side surface of the transparent member, and ii) a top surface of the solid-state imaging element, so as to fix the transparent member on the solid-state imaging element.

This structure causes the fillet to protect a surrounding edge of the transparent member, which can keep the transparent member from breaking against an unforeseeable impact in the manufacturing process.

The transparent member may be placed in contact and fixed with the protruding portions via silane-based organic compound.

According to this structure, a joining portion between each of the digital microlenses and the transparent member, as well as the digital microlenses and the transparent member, employs a glass structure, which makes possible further improving the solid-state imaging device in durability, compared with the case of using transparent adhesive made of an organic material.

Moreover, a method for manufacturing a solid-state imaging device in accordance with another aspect of the present invention includes: forming a solid-state imaging element on a semiconductor substrate; and placing and fixing a transparent member on the solid-state imaging element, wherein the forming the solid-state imaging element has: forming light receiving units on the semiconductor substrate; and forming digital microlenses each of which is arranged above an associated one of the light receiving units, the digital microlens has protruding portions and recessed portions, each of the protruding portions and the recessed portions being alternately arranged in a concentric pattern, and the placing and fixing the transparent member involves fixing the transparent member on the solid-state imaging element, so that the transparent member is placed in contact with the protruding portions, and the recessed portions make no contact with the transparent member.

According to the above, the top surfaces of the digital microlenses are placed in contact with the under surface of the transparent member. This makes possible reducing the thickness of the solid-state imaging device compared with the case where the transparent member is placed over the digital microlenses (or microlenses formed out of an organic material) via a void. Further, the solid-state imaging device in the first aspect of the present invention uses the digital microlenses to achieve improvement in heat-resistance and weather-resistance. Thus, the present invention can provide a method for manufacturing a thin solid-state imaging device which enjoys excellent heat-resistance and weather-resistance.

The placing and fixing may involve placing the transparent member in contact with the protruding portions via transparent adhesive, and fixing the transparent member on the solid-state imaging element.

This makes possible easily attaching the transparent member and the digital microlenses, using the transparent adhesive.

The placing and fixing may involve hydrophobizing a bottom surface and a side surface of each of the recessed portions, placing the transparent member in contact with the protruding portions via the transparent adhesive, and fixing the transparent member on the solid-state imaging element.

This makes possible keeping wettability little between the surfaces of the recessed portions of the digital microlenses and the transparent adhesive, which can prevent the transparent adhesive from flowing into each of the recessed portions and keep the void of the recessed portion from being filled with the transparent adhesive when applying the transparent adhesive on the top surface of each of the protruding portions.

The placing and fixing includes: placing the transparent member on the solid-state imaging element, and forming fillet bonding with i) a side surface of the transparent member, and ii) a top surface of the solid-state imaging element, and fixing the transparent member on the solid-state imaging element, the fillet being made of adhesive.

This causes the fillet to protect a surrounding edge of the transparent member, which can keep the transparent member from breaking against an unforeseeable impact in the manufacturing process.

The placing and fixing includes: forming a first silane-based organic compound layer on one of surfaces of the transparent member; forming a second silane-based organic compound layer on a surface of each of the protruding portions; and chemically bonding the first silane-based organic compound layer and the second silane-based organic compound layer, and fixing the transparent member on the solid-state imaging element.

According to the above, a joining portion between each of the digital microlenses and the transparent member, as well as the digital microlenses and the transparent member, employs a glass structure, which makes possible further improving the solid-state imaging device in durability, compared with the case of using transparent adhesive made of an organic material.

The above enables the present invention to provide a thin solid-state imaging device with excellent heat-resistance and weather-resistance and a method for manufacturing thereof.

### FURTHER INFORMATION ABOUT TECHNICAL BACKGROUND TO THIS APPLICATION

The disclosure of Japanese Patent Application No. 2008-307998 filed on Dec. 2, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of a solid-state imaging device according to a first embodiment of the present invention;

FIG. 2 is enlarged cross-sectional views of a digital microlens and a transparent member included in the solid-state imaging device according to the first embodiment of the present invention;

FIG. 3 is a cross-sectional view of a solid-state imaging device manufactured using a first method according to a second embodiment of the present invention;

FIG. 4 is a cross-sectional view of the solid-state imaging device in a manufacturing process of the first method according to the second embodiment of the present invention;

FIG. 5 is a cross-sectional view of the solid-state imaging device in a manufacturing process of the first method according to the second embodiment of the present invention;

FIG. 6 is a cross-sectional view of the solid-state imaging device in a manufacturing process of the first method according to the second embodiment of the present invention;

FIG. 7 is a cross-sectional view of the solid-state imaging device in a manufacturing process of the first method according to the second embodiment of the present invention;

FIG. 8 is a cross-sectional view of a solid-state imaging device manufactured using a second method according to the second embodiment of the present invention;

FIG. 9 is a cross-sectional view of the solid-state imaging device in a manufacturing process of the second method in the second embodiment of the present invention;

FIG. 10 is a cross-sectional view of the solid-state imaging device in a manufacturing process of the second method according to the second embodiment of the present invention;

FIG. 11 is a cross-sectional view of a solid-state imaging device manufactured using a third method according to the second embodiment of the present invention;

FIG. 12 is a cross-sectional view of the solid-state imaging device in a manufacturing process of the third method according to the second embodiment of the present invention;

FIG. 13 is a cross-sectional view of the solid-state imaging device in a manufacturing process of the third method according to the second embodiment of the present invention;

FIG. 14 illustrates a cross-sectional view of a conventional solid-state imaging device;

FIG. 15 illustrates a cross-sectional view of a digital microlens; and

FIG. 16 illustrates a top view of the digital microlens.

### DESCRIPTION OF THE PREFERRED EMBODIMENTS

Embodiments of a solid-state imaging device according to the present invention shall be described hereinafter in detail with reference to the drawings.

### First Embodiment

The solid-state imaging device according to the first embodiment of the present invention has each of digital microlenses arranged with a top surface of the digital microlens abutted on a transparent member. This realizes a thin solid-state imaging device.

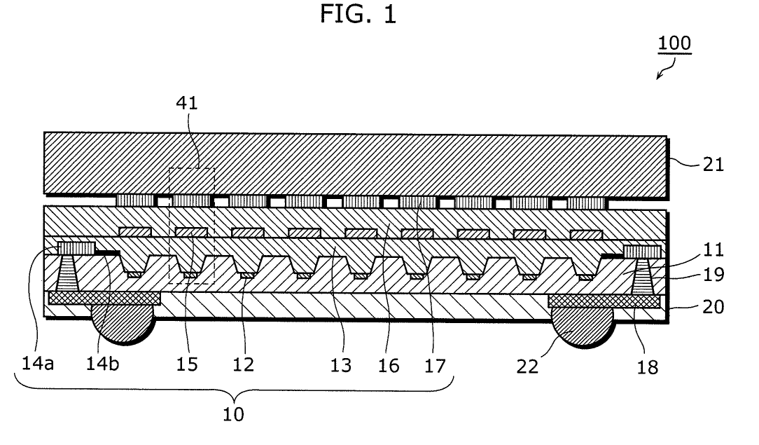

FIG. 1 is a cross-sectional view of a solid-state imaging device according to a first embodiment of the present invention.

A solid-state imaging device 100 in FIG. 1, structured in the Wafer Level Chip Size Package (WL-CSP), includes a solid-state imaging element 10, a semiconductor substrate 11, a metal line 18, a penetrating electrode 19, an insulating resin layer 20, a transparent member 21, and an outside electrode 22.

Formed on the semiconductor substrate 11, the solid-state imaging element 10 converts incident light into an electric signal. The solid-state imaging element 10 includes light receiving units 12, first planarizing film 13, an electrode portion 14a, a surrounding circuit unit 14b, color filters 15, second planarizing film 16, and digital microlenses 17.

Each of the light receiving units 12; namely a photodiode, is formed on a principal surface and in the middle of the semiconductor substrate 11 (top surface shown in FIG. 1) in a matrix. Each of the light receiving unit 12 converts incident light into an electric signal.

The first planarizing film 13 is formed on the light receiving units 12 and on the principle plane of the semiconductor substrate 11. Forming the first planarizing film 13 planarizes the surfaces of the semiconductor substrate 11 and the light receiving units 12. The first planarizing film 13 is made of, for example, acrylic resin.

Each of the color filters 15, corresponding to an associated one of the light receiving units 12, is formed above the associated light receiving unit 12. Specifically, the color filter 15 is formed on the first planarizing film 13, with a flat surface of the color filter 15 arranged directly above a flat surface of the associated light receiving unit 12. No other colors than a predetermined color (frequency band) are transmitted through the color filters 15. The light transmitted through the color filters 15 enters the light receiving unit 12 corresponding to the associated color filter 15.

The second planarizing film 16 is formed over the color filters 15 and the first planarizing film 13. Forming the second planarizing film 16 planarizes the color filters 15. The second planarizing film 16 is made of, for example, acrylic resin.

Each of the digital microlenses 17: corresponds to and is formed above an associated one of the color filters 15 and one of the light receiving units 12. Specifically, the digital microlens 17 is formed on the second planarizing film 16, with a flat surface of the digital microlens 17 arranged directly above the flat surfaces of the associated one of the color filters 15 and one of the light receiving units 12. The digital microlens 17 guides the incident light via the transparent member 21 to the color filter 15 (the light receiving unit 12) corresponding to the associated digital microlens 17.

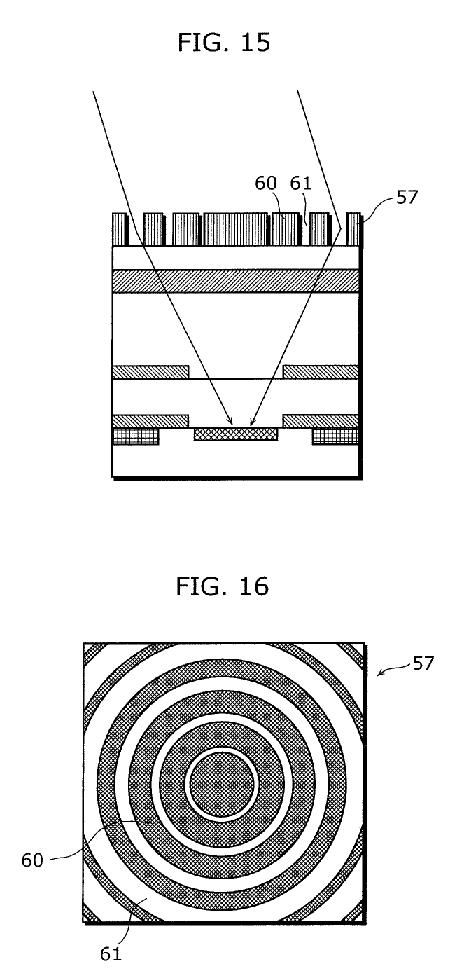

Here, the digital microlens 17 is similarly structured as, for example, the digital microlens 57 shown in FIGS. 15 and 17 is, and may be made of SiO₂.

The surrounding circuit unit 14b is formed: on a surface of the principle plane located in a surrounding portion of the semiconductor substrate 11; and around the light receiving units 12. The surrounding circuit unit 14b is a group of circuits processing electric signals converted by the light receiving units 12. Specifically, the surrounding circuit unit 14b selects a light receiving unit 12 reading an electric signal and amplifies the electric signal.

Formed on the principle plane of the semiconductor substrate 11, the electrode portion 14a; namely an electric pad, electrically connects an input-output terminal of the surrounding circuit unit 14b to the penetrating electrode 19.

Penetrating the semiconductor substrate 11 in a thickness direction, the penetrating electrode 19 electrically connects the electrode portion 14a and the metal line 18. The semiconductor substrate 11 is 100 nm to 300 nm in thickness, for example.

Formed on the back surface against the principle plane of the semiconductor substrate 11, the metal line 18 electrically connects the penetrating electrode 19 to the outside electrode 22. The metal line 18 is made of copper, for example.

The insulating resin layer 20 covers the metal line 18, as well as exposes part of the metal line 18 through an opening portion included therein.

Formed in the opening portion of the insulating resin layer 20, the outside electrode 22 is electrically connected to the metal line 18. The outside electrode 22 is made of a lead-free soldering material having Sn—Ag—Cu composition, for example.

It is noted that an insulated layer not shown in FIG. 1 electrically insulates all the constituent elements, except the electrode portion 14a, of the solid-state imaging element 10 from the penetrating electrode 19 and the metal line 18. In addition, a conventional structure can be applied to that of an image sensor package having a penetrating electrode.

The transparent member 21 is formed to provide cover over the digital microlenses 17. The transparent member 21, which may be a glass board, is a transparent substrate for protecting the digital microlenses 17.

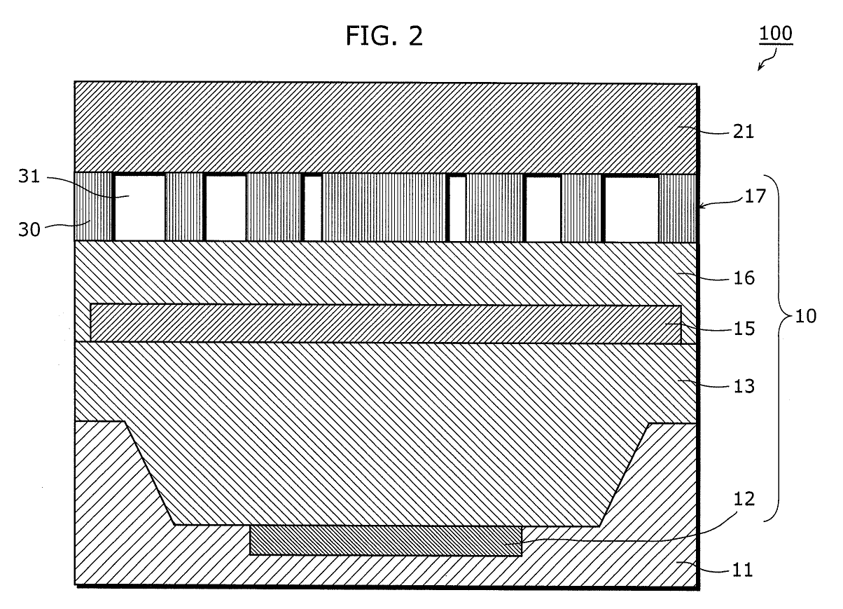

FIG. 2 is an enlarged view of an area 41 shown in FIG. 1; that is, a cross-sectional view illustrating a structure of a bonding face between the digital microlens 17 and the transparent member 21.

The digital microlens 17 has protruding portions 30 and recessed portions 31 each alternately arranged in a concentric pattern. The protruding portions 30 of the digital microlens 17 are placed in contact with the transparent member 21. Meanwhile, the recessed portions 31 of the digital microlens 17 make no contact with the transparent member 21. In other words a void is found between the recessed portions 31 and the transparent member 21.

The transparent member 21 may be a solid stable at a room temperature and has a transmittance of 90% with respect to a wavelength in a visible region. Preferably, the transparent member 21 may be made of glass since the glass enjoys adhesiveness to a material of the digital microlenses 17 and durability as the digital microlenses 17 is durable. Here, the planar shape (two-dimensionally observed shape) of the transparent member 21 is approximately as large as that of the solid-state imaging device 100 (the semiconductor substrate 11), as shown in FIG. 1. It is noted that the planar shape of the transparent member 21 may be bigger or smaller in size than that of the solid-state imaging device 100. The size of the planar shape of the transparent member 21 may be determined based on a purpose thereof in relation between image characteristics maintenance and a mounting area.

Regarding the solid-state imaging device 100 according to the first embodiment of the present invention, the digital microlenses 17 and the transparent member 21 are directly bonded together, as described above. This realizes a thin solid-state imaging device.

Further, the solid-state imaging device 100 uses the digital microlenses 17 to condense outside light on the light receiving units 12, the digital microlenses 17 which are made of an inorganic material as a refraction index adjusting medium. Compared with a solid-state imaging device using a microlens made of an organic material, this significantly improves durability of the solid-state imaging device 100 according to the first embodiment of the present invention.

In addition, the penetrating electrode 19 penetrating the semiconductor substrate 11. allows the solid-state imaging device 100 to realize the WL-CSP structure. As well as achieving the durability, this also makes possible minimizing the solid-state imaging device 100 according to the first embodiment of the present invention.

It is noted that the SiO₂ on the recessed portions 31 of the digital microlens 17 shown is completely removed in FIG. 2; meanwhile, the SiO₂ may be left on some portions of the recessed portions 31. In other words, the digital microlens 17 includes the protruding portions 30 each having first thickness (thickness in a vertical direction in FIG. 2), and the recessed portions 31 each having second thickness which is thinner than the first thickness. Moreover, each of the recessed portions 31 may be different in thickness. In other words, the protruding portion 30 placed in contact with the transparent member 21 is greatest out of the irregularities formed on the digital microlens 17 in thickness.

### Second Embodiment

Described in a second embodiment of the present invention are manufacturing methods of a solid-state imaging device according to the first embodiment and advantages of each of solid-state imaging devices manufactured with a use of corresponding manufacturing method.

The following three methods are used to fix the transparent member 21 on the digital microlenses 17.

A first method involves using transparent adhesive to directly attach the surfaces of the protruding portions 30 of the digital microlenses 17 to the transparent member 21. A second method involves i) forming fillet, so that adhesive forming the fillet bonds with a surrounding edge face of the transparent member 21 and a surrounding top surface of the solid-state imaging element 10, and ii) fixing the transparent member 21 on the solid-state imaging element 10 via the fillet. A third method involves using organic silane-based compound to directly and chemically join the surfaces of the protruding portions of 30 of the digital microlenses 17 and the transparent member 21 (glass).

Described first is the method (first method) for directly attaching, via the transparent adhesive, the surfaces of the protruding portions 30 of the digital microlenses 17 to the transparent member 21.

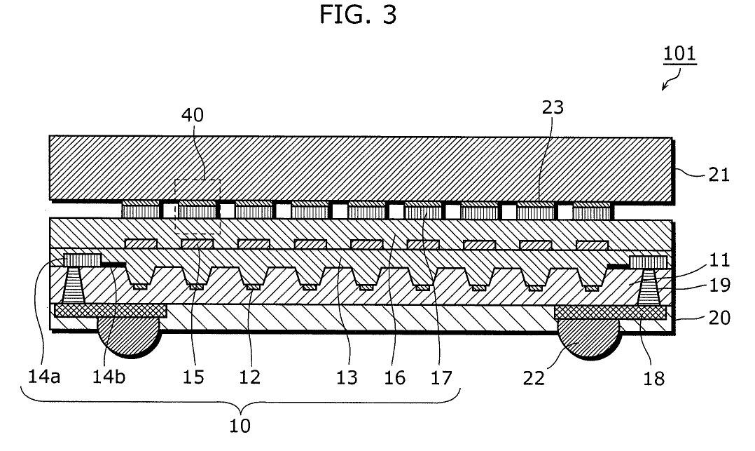

FIG. 3 is a cross-sectional view showing a structure of a solid-state imaging device 101 manufactured with the first method. It is noted in FIG. 3 that the same numerical references are shared with regard to the elements identical to those in FIG. 1.

Regarding the solid-state imaging device 101 in FIG. 3, transparent adhesive 23 attaches top surfaces of the protruding portions 30 of the digital microlenses 17 to an under surface of the transparent member 21. The transparent adhesive 23 may be a generally-used one. Preferably, a minimum necessary amount of the transparent adhesive 23 shall be evenly applied to the surface of the transparent member 21 in order to prevent the transparent adhesive 23 from flowing into each of recessed portions 31 of the digital microlens 17. The generally-used transparent adhesive 23, which is preferable process-wise, can readily attach the transparent member 21 to the digital microlenses 17.

In using the first method, a silane coupling agent is preferably used to hydrophobize in advance the surfaces of recessed portions 31. This makes possible keeping wettability little between the surfaces of the recessed portions 31 of the digital microlenses 17 and the transparent adhesive 23, which can prevent the transparent adhesive 23 from flowing into each of the recessed portions 31 and keep the void of the recessed portion 31 from being filled with the transparent adhesive 23.

Described hereinafter is a flow of a method for manufacturing the solid-state imaging device 101.

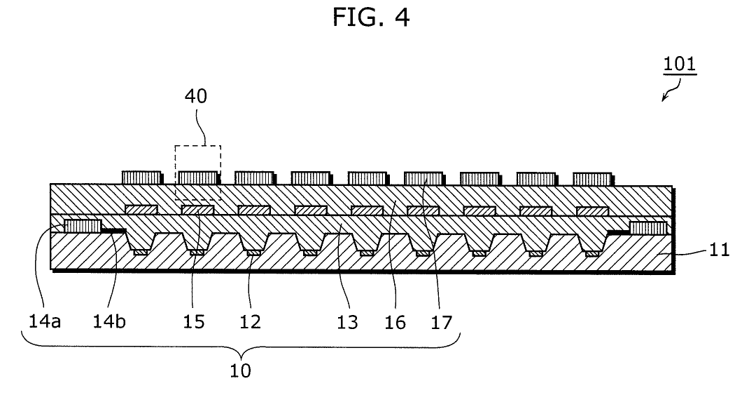

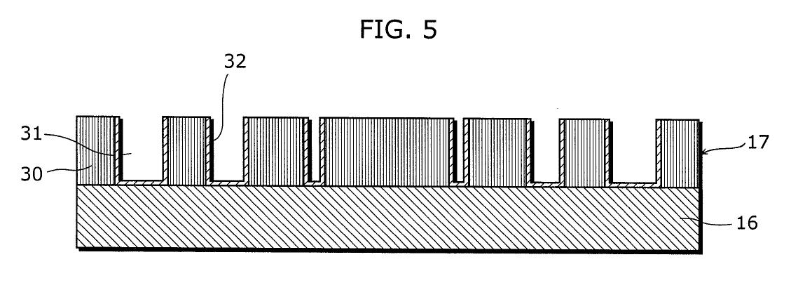

FIGS. 4 to 7 are cross-sectional views of the solid-state imaging device 101 in a manufacturing process of the first method. FIGS. 5 to 7 provide magnified views of an area 40 shown in FIG. 4.

First, the solid-state imaging element 10 is formed on the semiconductor substrate 11. Specifically, each of the light receiving units 12, the surrounding circuit unit 14b, and the electrode portion 14a are formed on the semiconductor substrate 11, followed by sequentially forming the first planarizing film 13, each of the color filters 15, the second planarizing film 16, and each of the digital microlenses 17. This provides a structure shown in FIG. 4.

It is noted that techniques other than the technique to fix the transparent member 21 on the digital microlenses 17 are well-known, and a detailed description thereof shall be omitted.

Next, the transparent member 21 is placed and fixed on the solid-state imaging element 10.

Specifically, the silane coupling agent is used to hydrophobize a bottom surface and a side surface of each of the recessed portions 31 of the digital microlens 17, as shown in FIG. 5. This hydrophobization forms a hydrophobized layer 32 on the bottom surface and the side surface of the recessed portion 31.

In forming the hydrophobized layer 32 on the bottom surface and the side surface of the recessed portion 31, the transparent adhesive 23 is directly applied only to the top surface of the protruding portion 30 of each of the digital microlenses 17, instead of applying to the entire undersurface of the transparent member 21. This can fix the transparent member 21 on the digital microlenses 17. The advantageous effect of the above is that forming the hydrophobized layer 32 allows the transparent adhesive 23 to be applied only to a required portion, which makes possible reducing the use of the transparent adhesive 23 to the minimum.

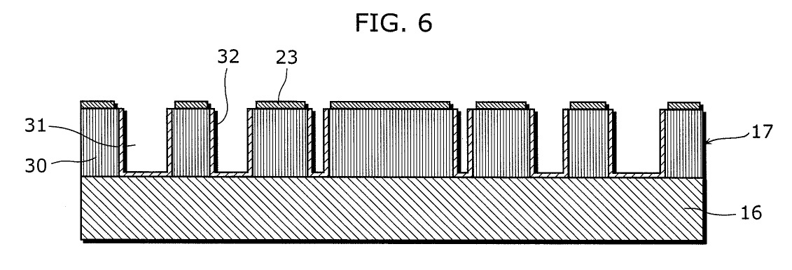

Next, the transparent adhesive 23 is applied to each top surfaces of the protruding portion 30, as shown in FIG. 6.

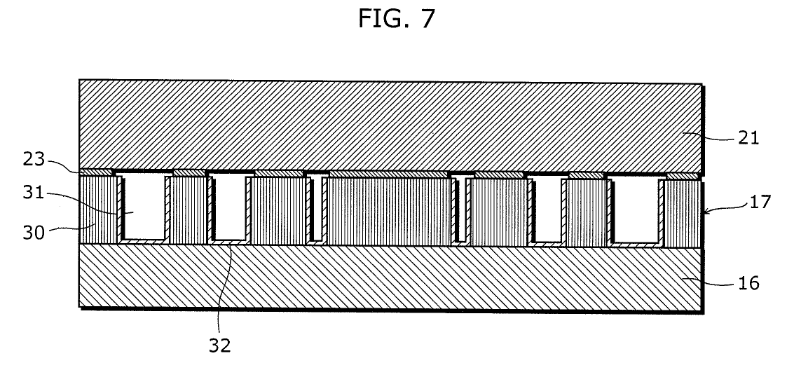

Then, the transparent member 21 and the protruding portions 30 are placed in contact via the transparent adhesive 23, as shown in FIG. 7. The transparent adhesive 23 fixes the transparent member 21 on the solid-state imaging element 10. Here, the transparent adhesive 23 makes no contact with the bottom surface or the side surface of the recessed portion 31.

Next, the penetrating electrode 19, the metal line 18, the insulating resin layer 20, and the outside electrode 22 are sequentially formed.

This forms the solid-state imaging device 101 shown in FIG. 3.

Described next is the method for forming fillet, so that the adhesive forming the fillet bonds with the surrounding edge face of the transparent member 21 and the surrounding top surface of the solid-state imaging element 10 (the second method).

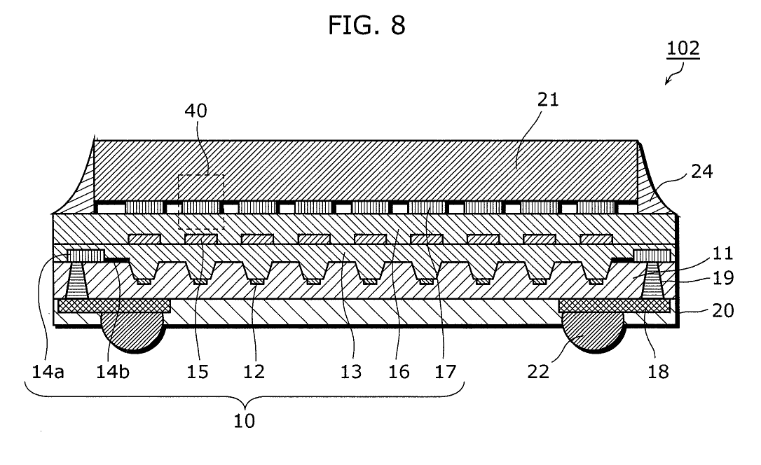

FIG. 8 is a cross-sectional view showing a structure of a solid-state imaging device 102 manufactured with the second method. It is noted that the same numerical references are shared with regard to the elements identical to those in FIG. 1.

Regarding the solid-state imaging device 102 shown in FIG. 8, fillet 24 which is made of adhesive bonds with the surrounding edge face (side surface) of the transparent member 21 and the surrounding top surface of the solid-state imaging element 10 (the surrounding top surface of the second planarizing film 16). The fillet 24 fixes the transparent member 21 on the solid-state imaging element 10.

Even though adhesive forming the fillet 24 should not necessarily be specific one as far as the adhesive is well-known in general, epoxide-based or acrylic adhesive is preferable in view of excellent workability and curability.

In addition, the height of the fillet 24 developing on the side surface of the transparent member 21 is preferably not greater than the thickness of the transparent member 21. Because, in the case where the height of the fillet 24 developing on the side surface of the transparent member 21 exceeds the thickness of the transparent member 21, the adhesive consequently covers a surrounding portion of the top surface of the transparent member 21. The adhesive covering the transparent member 21 diffuses incident light entering therein. This interferes with travel of the incident light to the light receiving units 12, which causes a decrease in light-receiving efficiency of the solid-state imaging element 10.

Moreover, the second method for attaching the transparent member 21 to the solid-state imaging element 10 causes the fillet 24 to protect a surrounding edge face of the transparent member 21. This can keep the transparent member 21 from breaking (such as a side-face crack) against an unforeseeable impact in the manufacturing process.

Described hereinafter is a flow of a method for manufacturing the solid-state imaging device 102.

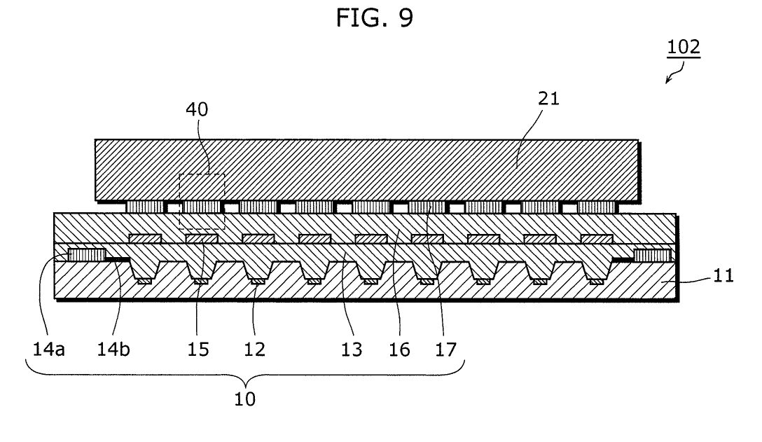

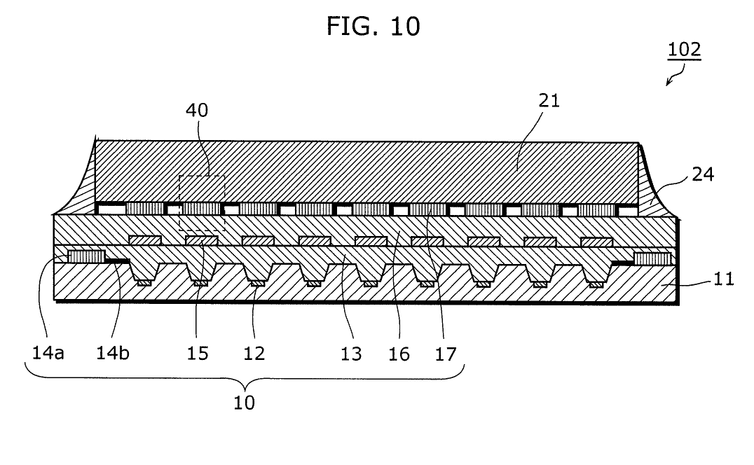

FIGS. 9 and 10 are cross-sectional views of the structure of the solid-state imaging device 102 in a manufacturing process of the second method.

First, the solid-state imaging element 10 is formed on the semiconductor substrate 11. This forms a structure similar to that of the solid-state imaging device 101 shown in FIG. 4.

Next, the transparent member 21 is placed and fixed on the solid-state imaging element 10.

Specifically, as shown in FIG. 9, the transparent member 21 is placed over the digital microlenses 17 in order to cover an area in which the digital microlenses 17 are arranged.

Next, as shown in FIG. 10, the fillet 24 is formed to bond with i) the side surface of the placed transparent member 21, and ii) the surrounding top surface of the solid-state imaging element 10 (the top surface of the second planarizing film 16 above the surrounding portion of the semiconductor substrate 11). The fillet 24 fixes the transparent member 21 on the digital microlenses 17.

Next, the penetrating electrode 19, the metal line 18, the insulating resin layer 20, and the outside electrode 22 are sequentially formed.

This forms the solid-state imaging device 102 shown in FIG. 8.

Described next is the method for directly and chemically joining, via organic silane-based compound, the surfaces of the protruding portions of 30 of the digital microlenses 17 and the under surface of the transparent member 21.

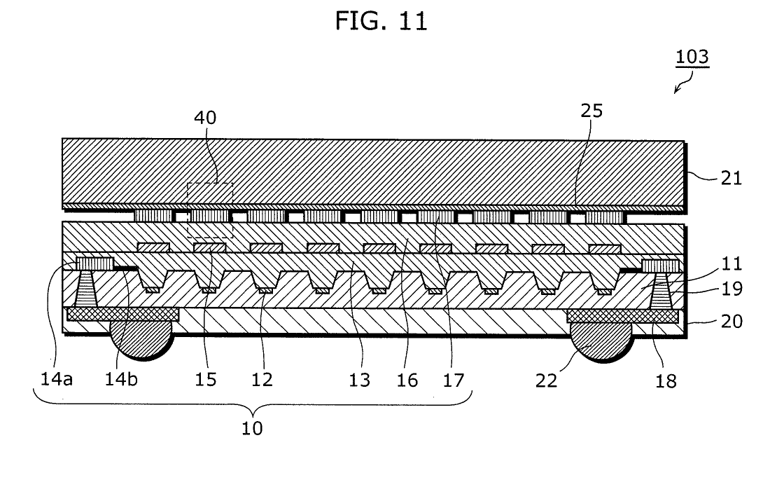

FIG. 11 is a cross-sectional view of a solid-state imaging device 103 manufactured using the third method. It is noted that the same numerical references are shared with regard to the elements identical to those in FIG. 1.

Regarding the solid-state imaging device 103 shown in FIG. 11, the transparent member 21 is made of glass. Here, a silane-based organic compound layer 25 is formed on the surface of the transparent member 21 making contact with the digital microlenses 17, the silane-based organic compound layer 25 which is top-coated with the silane coupling agent. In addition, the surfaces of the protruding portions 30 of the digital microlenses 17 are also top-coated with the silane coupling agent. Hence, the surfaces of the protruding portions 30 and the silane-based organic compound layer 25 on the transparent member 21, both top-coated, are directly attached via chemical bonding.

In this case, a joining portion between each of the digital microlenses 17 and the transparent member 21, as well as the digital microlenses 17 and the transparent member 21, employs a glass structure. This makes possible further improving the solid-state imaging device 103 in durability, compared with the case of using transparent adhesive made of an organic material.

Described hereinafter is a flow of a method for manufacturing the solid-state imaging device 103.

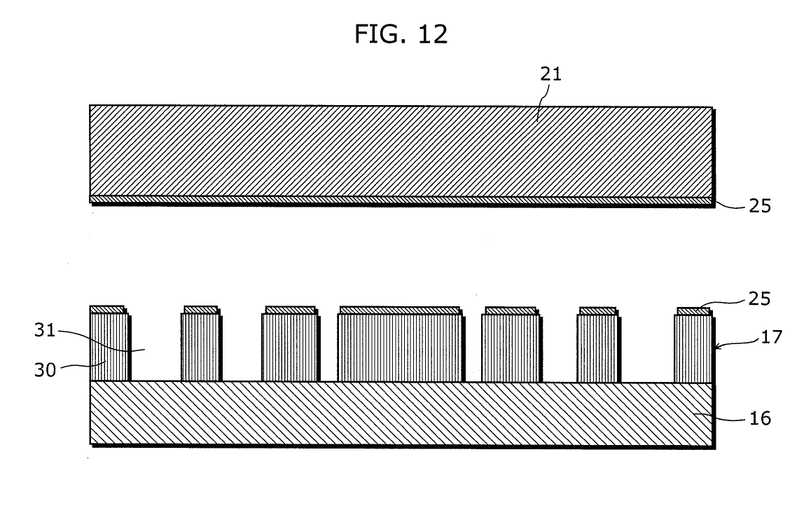

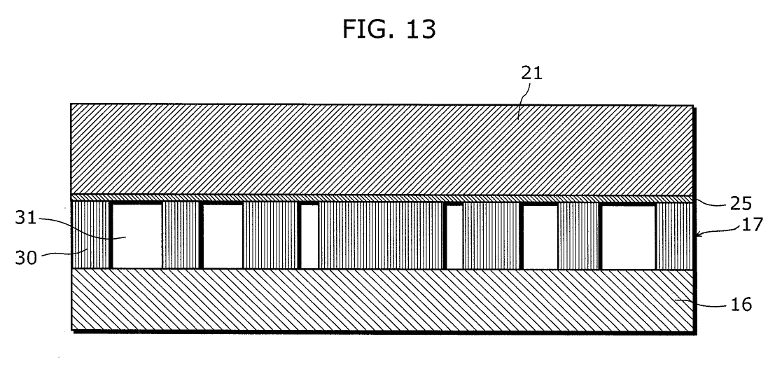

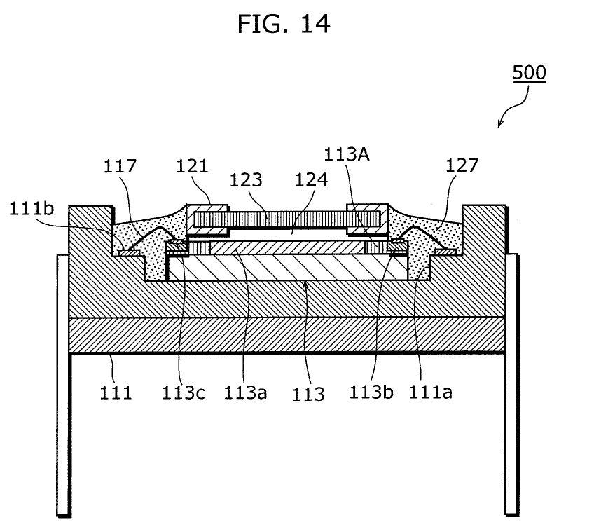

FIGS. 12 and 13 are cross-sectional views showing a structure of the solid-state imaging device 103 in a manufacturing process in the third method. FIGS. 12 and 13 provide magnified views of the area 40 shown in FIG. 11.

First, the solid-state imaging element 10 is formed on the semiconductor substrate 11. This forms a structure similar to that of the solid-state imaging device 101 shown in FIG. 4.

Next, the transparent member 21 is placed and fixed on the solid-state imaging element 10.

Specifically, as shown in FIG. 12, the silane coupling agent is used to provide a topcoat, so that the silane-based organic compound layer 25 is formed on one of the surfaces (under surface) of the transparent member 21. In addition, top-coating with a use of the silane coupling agent forms the silane-based organic compound layer 25 on the top surface of each of the protruding portions 30.

Next, as shown in FIG. 13, chemically bonded are the silane-based organic compound layer 25 on the transparent member 21 and the silane-based organic compound layer 25 on the protruding portions 30. The chemically-bonded silane-based organic compound layer 25 fixes the transparent member 21 on the solid-state imaging element 10. Thus, the transparent member 21 and the protruding portions 30 are placed in contact and fixed via the silane-based organic compound layer 25.

Next, the penetrating electrode 19, the metal line 18, the insulating resin layer 20, and the outside electrode 22 are sequentially formed.

This forms the solid-state imaging device 103 shown in FIG. 11.

It is noted that in the case where the transparent member 21 is made of glass, the transparent member 21 (glass) and the protruding portions 30 of the digital microlenses 17 can be directly attached via anodic bonding.

Described above are the solid-state imaging devices 100, 101, 102, and 103 according to the first and second embodiments of the present invention; meanwhile, the present invention shall not be limited to the embodiments.

In the first and second embodiments, for example, the solid-state imaging devices 100, 101, 102, and 103 employ the WL-CSP structure; instead, the solid-state imaging devices 100, 101, 102, and 103 may employ another package.

Further, in the second embodiment, each of the first to third methods is separately described; meanwhile, two or more of the first to third methods may be combined.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to solid-state imaging devices, in particular, to a solid-state imaging device having the CSP structure.

What is claimed is:

1. A solid-state imaging device comprising:
a semiconductor substrate;
a solid-state imaging element formed on said semiconductor substrate; and
a transparent member placed on said solid-state imaging element,
wherein said solid-state imaging element includes:
light receiving units each of which is formed on said semiconductor substrate; and
digital microlenses each of which is formed above an associated one of said light receiving units,
each of said digital microlenses has protruding portions and recessed portions, each of said protruding portions and said recessed portions being alternately arranged in a concentric pattern, and
said protruding portions are placed in contact with said transparent member, and said recessed portions make no contact with said transparent member.

2. The solid-state imaging device according to claim 1,
wherein said transparent member is placed in contact and fixed with said protruding portions via the transparent adhesive, and
a bottom surface and a side surface of each of said recessed portions make no contact with the transparent adhesive.

3. The solid-state imaging device according to claim 2,
wherein the bottom surface and the side surface of each of said recessed portions are hydrophobized so as to form a hydrophobized layer.

4. The solid-state imaging device according to claim 1, further comprising
fillet which is made of adhesive and bonds with i) a side surface of said transparent member, and ii) a top surface of said solid-state imaging element, so as to fix said transparent member on said solid-state imaging element.

5. The solid-state imaging device according to claim 1,
wherein said transparent member is placed in contact and fixed with said protruding portions via silane-based organic compound.

6. A method for manufacturing a solid-state imaging device, comprising:
forming a solid-state imaging element on a semiconductor substrate; and
placing and fixing a transparent member on the solid-state imaging element,
wherein said forming the solid-state imaging element includes:
forming light receiving units on the semiconductor substrate; and
forming digital microlenses each of which is arranged above an associated one of the light receiving units,
the digital microlens has protruding portions and recessed portions, each of the protruding portions and the recessed portions being alternately arranged in a concentric pattern, and
said placing and fixing the transparent member involves fixing the transparent member on the solid-state imaging element, so that the transparent member is placed in contact with the protruding portions, and the recessed portions make no contact with the transparent member.

7. The method for manufacturing the solid-state imaging device according to claim 6,
wherein said placing and fixing involves placing the transparent member in contact with the protruding portions via transparent adhesive, and fixing the transparent member on the solid-state imaging element.

8. The method for manufacturing the solid-state imaging device according to claim 7,
wherein said placing and fixing involves hydrophobizing a bottom surface and a side surface of each of the recessed portions, placing the transparent member in contact with the protruding portions via the transparent adhesive, and fixing the transparent member on the solid-state imaging element.

9. The method for manufacturing the solid-state imaging device according to claim 6,
wherein said placing and fixing includes:
placing the transparent member on the solid-state imaging element, and
forming fillet bonding with i) a side surface of said transparent member, and ii) a top surface of said solid-state imaging element, and fixing the transparent member on the solid-state imaging element, the fillet being made of adhesive.

10. The method for manufacturing the solid-state imaging device according to claim 6,
wherein said placing and fixing includes:
forming a first silane-based organic compound layer on one of surfaces of the transparent member;
forming a second silane-based organic compound layer on a surface of each of the protruding portions; and
chemically bonding the first silane-based organic compound layer and the second silane-based organic compound layer, and fixing the transparent member on the solid-state imaging element.
